(19) United States
(12) Patent Application Publication
(10) Pub. No.: US 2023/0197664 A1
(43) Pub. Date: Jun. 22, 2023

(54) SOLID COMPONENT COUPLED TO DIES IN MULTI-CHIP PACKAGE USING DIELECTRIC-TO-DIELECTRIC BONDING

(71) Applicant: Intel Corporation, Santa Clara, CA (US)

(72) Inventors: Xavier F. Brun, Hillsboro, OR (US); Yuting Wang, Chandler, AZ (US)

(73) Assignee: Intel Corporation, Santa Clara, CA (US)

(21) Appl. No.: 17/558,291

(22) Filed: Dec. 21, 2021

(51) Int. Cl. H01L 23/00; H01L 25/18; H01L 25/065; H01L 23/367; H01L 25/00; H01L 21/56

(52) U.S. Cl. CPC H01L 24/29; H01L 25/18; H01L 25/0652; H01L 25/0655; H01L 24/32; H01L 23/3675; H01L 25/50; H01L 24/83; H01L 24/96; H01L 21/568; H01L 21/561; H01L 2224/83132; H01L 2224/8389; H01L 2224/32145; H01L 2224/32245; H01L 2224/29188; H01L 2924/05042; H01L 2924/05442; H01L 2924/05994; H01L 2224/83193; H01L 24/27; H01L 23/3736

(57) ABSTRACT

A semiconductor package includes a semiconductor subassembly disposed on a package substrate and including: a first layer including first dies, and an encapsulation material encapsulating the first dies; a second layer adjacent the first layer and including a substrate; a solid component disposed on the first layer; and an interface layer disposed between and mechanically bonding the solid component and the first layer. The interface layer provides a direct dielectric-to-dielectric bond including a first dielectric sublayer directly adjacent the first layer, and a second dielectric sublayer directly adjacent the first dielectric sublayer and including an amorphous material. Second dies may be disposed on the package substrate adjacent the semiconductor subassembly. A heat spreader is disposed over the semiconductor subassembly and the second dies; and a TIM is coupled to the heat spreader at one side thereof, and to respective ones of the semiconductor subassembly and the one or more dies at another side thereof.

### TECHNICAL FIELD

This disclosure relates generally to thermal, scaling and warpage control solutions for three-dimensional (3D) stacked dies in multi-chip packages (MCPs).

### BACKGROUND

MCP fabrication according to the state-of-the-art faces a number of technical challenges including limited top die thickness allowance (currently from about 170 μm to about 280 μm) due to current controlled collapse chip connection (C4), and temporary carrier limitations for top dies, and also including stringent requirements for die reconstitution on the temporary carrier during fabrication of the MCP. The latter is in part because the adhesive used on top die temporary carriers disadvantageously accounts for relatively large top die motion on the carrier adhesive, in this way compromising electrical feature pitch and package scaling. In addition, current MCP fabrication processes may lead to high wafer warpage.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIGS. 1A and 1B illustrate side cross-sectional views of two different MCPs according to the state of the art.

FIG. 2 illustrates a side cross-sectional view of a temporary carrier and top dies assembly according to an example.

FIG. 3A illustrates a side cross-sectional view of a MCP subassembly including top dies on a substrate coupled to a solid component according to an embodiment.

FIG. 3B illustrates a side cross-sectional view of a MCP including the MCP subassembly of FIG. 3A according to an embodiment.

FIG. 3C shows a electron microscopy image of a direct dielectric-to-dielectric bond according to an example.

FIG. 4 illustrates a side cross-sectional view of a subassembly including a permanent carrier/solid component according to some embodiments supporting top dies thereon.

FIG. 5A illustrates a side cross-sectional view of a MCP based on a chip first architecture including top dies with underbumps according to a first embodiment.

FIG. 5B illustrates a side cross-sectional view of a MCP based on a chip first architecture including bumpless dies according to a second embodiment.

FIG. 5C illustrates a side cross-sectional view of a MCP based on a chip last architecture according to a third embodiment.

FIG. 6 illustrates a flow for a method to make a MCP similar to the MCP of FIG. 5A according to one embodiment.

FIG. 7 illustrates a flow for a method to make a MCP similar to the MCP of FIG. 5B or 5C according to some embodiments.

FIG. 8 is a cross-sectional side view of an integrated circuit device assembly that may include a MCP in accordance with any of the embodiments disclosed herein.

FIG. 9 is a block diagram of an example electrical device that may include a MCP assembly, in accordance with any of the embodiments disclosed herein.

FIG. 10 is a flow chart of a process according to some embodiments.

### DETAILED DESCRIPTION

Some embodiments provide a semiconductor subassembly for a MCP, where the subassembly comprises: a first layer including one or more dies, and an encapsulation material encapsulating the one or more dies; a second layer adjacent the first layer and electrically coupled thereto, the second layer including a substrate; a solid component disposed on the first layer; and an interface layer disposed between and mechanically bonding the solid component and the first layer, the interface layer providing a direct dielectric-to-dielectric bond including a first dielectric sublayer directly adjacent the first layer, and a second dielectric sublayer directly adjacent the first sublayer and including an amorphous material.

The “solid component” as referred to herein may include a cyrstalline, semi-crystalline or amorphous solid component or element that may comprise silicon, silicon carbide, glass, ceramic or any material or combination of materials that can provide structural support and or thermal transfer, dissipation and/or spreading from top dies of a multi-chip package. The solid component may include a passive component, such as a passive heat spreader interposer.

The term “passive” as used herein is used to distinguish the solid component from “active” components or dies where active dies include circuitry electrically/conductively coupled to interconnects that are themselves electrically coupled to a substrate. A passive component or die on the other hand may or may not have circuitry (as it is possible that dead/discarded ICs would be used as passive/dummy components) but if it does have circuitry that circuitry is not be electrically coupled through interconnects to the substrate.

Details of some embodiments will be described in further detail below.

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

Some embodiments seek to leverage a permanent passive heat-spreader interposer including a dielectric as an intermediate integrated heat spreader in a multi-chip package (MCP) and in this way provide a simple, practical and effective MCP thermal solution for MCP stacked microelectronic layers. The dielectric material of the passive heat-spreader interposer may include one or more of various materials such as Si or SiC for improved thermal conductivity. The passive heat-spreader interposer may have a thickness to compensate for a height mismatch as between the top dies (dies of the MCP closest to the passive heat-spreader interposer, also sometimes referred to herein as “first dies”) on the one hand, and side dies (sometimes referred to herein as “second dies”—such as high bandwidth memory (HBM) as part of the MCP) on the other hand. For side dies having a larger thickness than the top dies, a passive heat-spreader interposer according to embodiments may fill in enough of a gap between a backside of the top dies and a heat spreader coupled to the top dies and the side dies such that a single thermal interface material (TIM) may be placed between the dies and the heat spreader if desired.

According to some embodiments, the passive heat-spreader interposer may be coupled to the top dies through a direct dielectric-to-dielectric bond between a layer of the MCP that includes the top dies, and the passive heat-spreader interposer. A surface preparation of the bond interface (between the passive heat-spreader interposer and the MCP layer that includes the top dies—hereinafter “first layer”) may be performed, which may require provision of a SiN (or SiO or SiCN can also be leveraged but will provide higher contact resistance) layer, for example by way of deposition on the first layer, and chemical mechanical polishing (CMP) of the same to ensure flatness of the stack prior to the direct dielectric-to-dielectric bonding.

Embodiments advantageously allow the fabrication of MCPs with dies having a wide range of thicknesses (e.g., HBMs having a thickness of about 720 μm), which makes possible a single layer (possibly including sublayers) of TIM to couple both the side dies (such as HBMs) and top dies of a MCP to an integrated heat spreader (HIS). Embodiments therefore promote a more efficient thermal dissipation solution than that of the state-of-the-art.

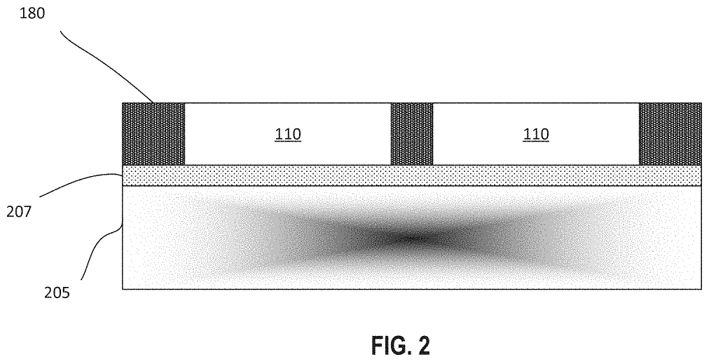

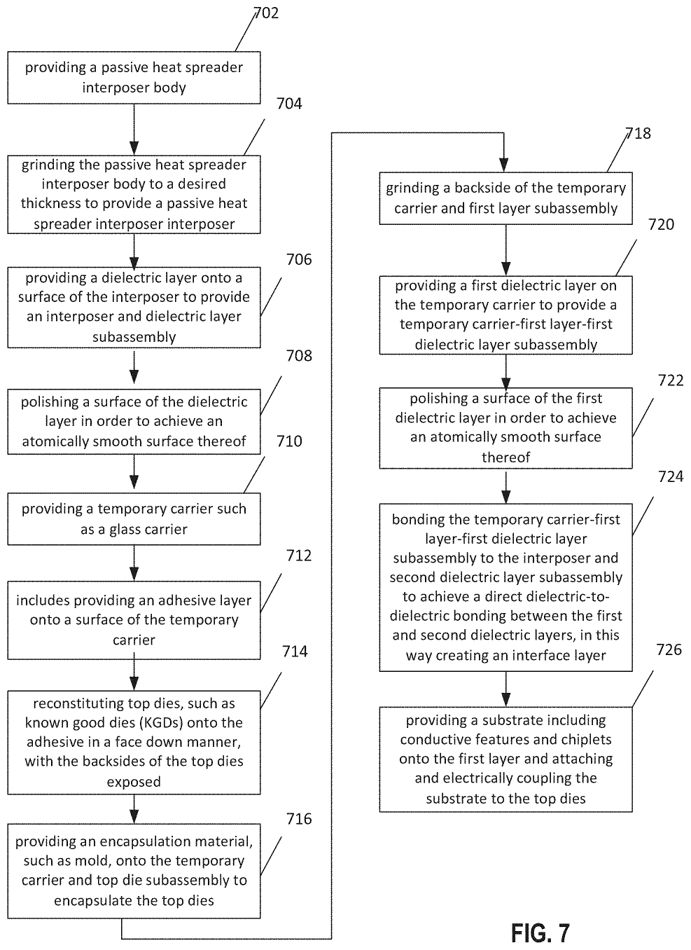

In addition, some embodiments that envisage doing away with the use of a temporary top die carrier (as will be explained in further detail in the context of FIGS. 2 and 7) advantageously allow more predictable control of a positioning of top dies during MCP fabrication, in this manner allowing tighter conductive feature pitches on an underlying layer of the MCP that are to be electrically coupled to the top dies (hereinafter “second layer”), and thus offering much more flexible scaling solutions as compared with the state-of-the-art. For example, some embodiments may reduce epoxy molding compound (EMC) impact in die-to-die (D2D) spacing).

Some embodiments advantageously provide, more than about 25% thermal improvement for a MCP including a passive heat-spreader interposer according to some embodiments. Furthermore, in the air-cooled solution space, some embodiments may have significant impact on a MCP product's design and feasibility. As a result, embodiments may have a measurable impact on disaggregated and heterogenous packages.

Additionally, a passive heat-spreader interposer according to some embodiments may significantly improve MCP fabrication yield and lead to cost savings, reduce wafer-level warpage risk.

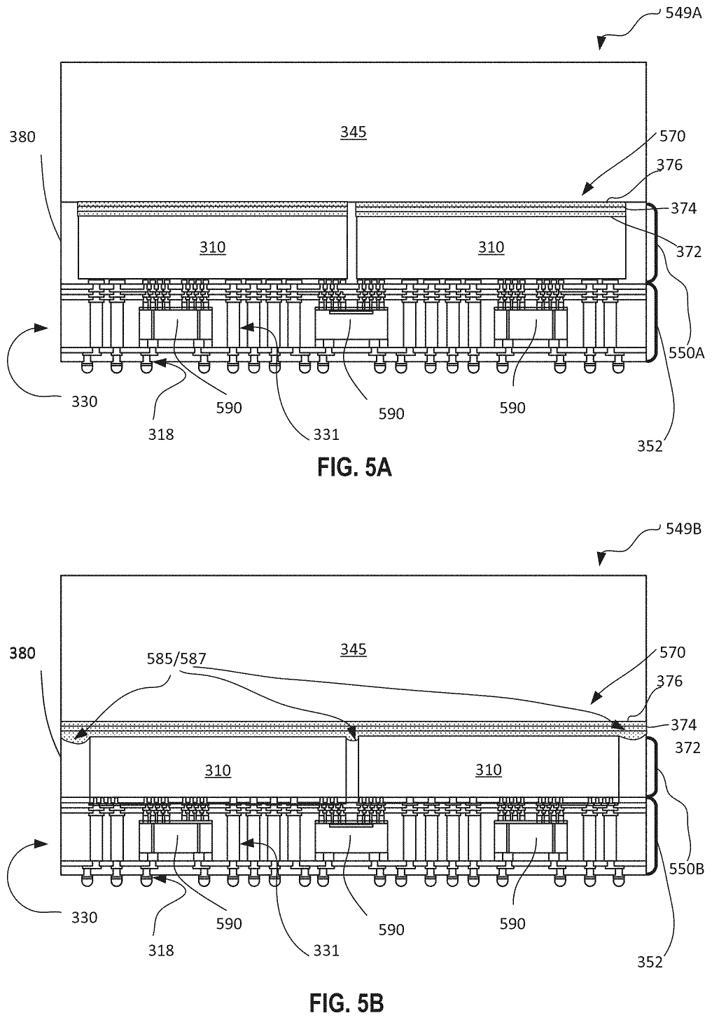

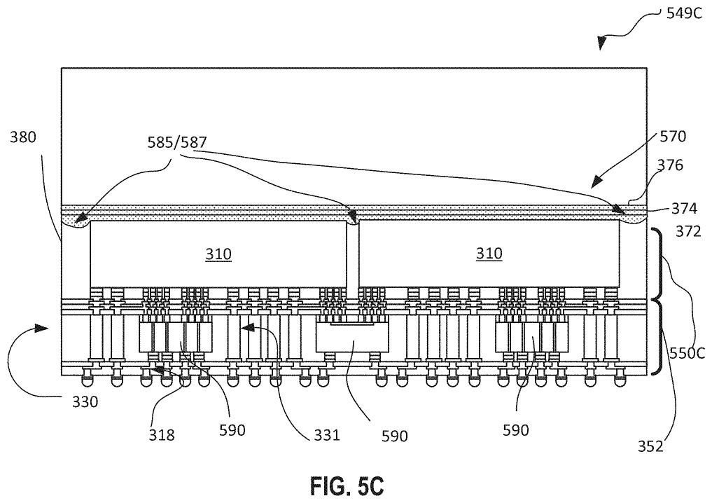

Embodiments as described herein can be integrated as part of the process flow with minimal additional steps, and are capable of being implemented in a number of MPC architectures and fabrication approaches, including, for example, a chip first architecture with top die underbumps (as will be explained in more detail in relation to FIG. 5A), a chip first architecture with bumpless top dies (as will be explained in more detail in relation to FIG. 5B), or a chip last architecture (as will be explained in more detail in relation to FIG. 5C).

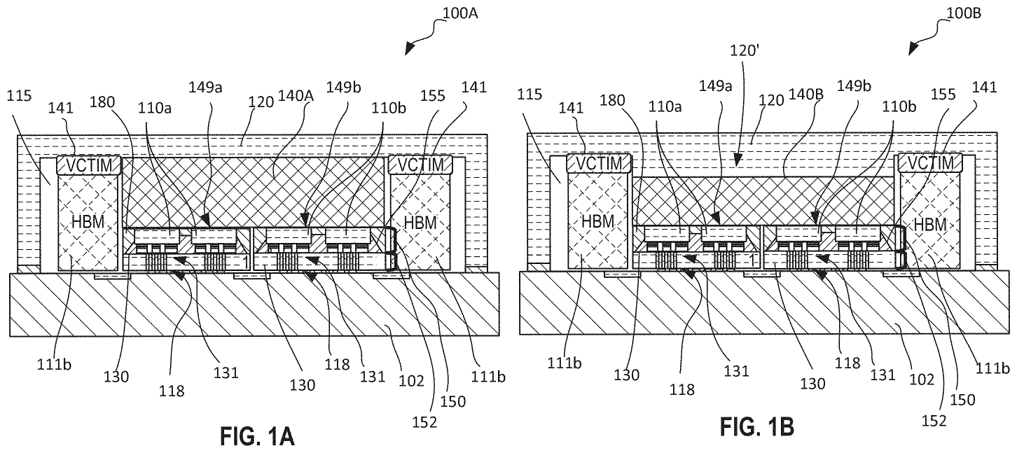

An explanation will now follow below regarding the state-of-the-art in the context of FIGS. 1A and 1B.

FIGS. 1A and 1B are side cross-sectional views of two multichip packages (MCPs) 100A/100B according to the state-of-the-art which have aimed to address the above technical problems. FIGS. 1A and 1B are different in that, in FIG. 1B, the heat spreader 120 includes an extension 120′ extending therefrom in a direction toward MCP subassemblies 149 , whereas, in FIG. 1A, the heat spreader 120 does not include such an extension. More details are provided below regarding the MCPs 100A and 100B of FIGS. 1A and 1B.

The state-of-the-art solutions shown in FIGS. 1A and 1B, in order to provide heat dissipation from components of the MCPs 100A and 100B, which include top dies 110 having thinner size limits because limitations of current tools (top dies denoted 110a/110b in FIGS. 1A/1B), and which further include the much thicker side dies 111 (denoted 111a/111b in FIGS. 1A/1B), propose providing either a very thick TIM 140A as shown in FIG. 1A, or a thick TIM 140B as shown in FIG. 1B, along with a heat spreader 120 that includes an extension 120′ extending therefrom toward the TIM 140B in order to accommodate the differing heights between the side dies 111 on the one hand, and of the top dies 110 on the other hand.

Side dies 111 are thermally coupled to the heat spreader 120 by way of TIMs 141.

In addition, even without the current tool constraints on the thickness of the top dies, for example for dies having a thickness of 720 μm, warpage of the die wafer is expected to be significant and therefore not practical for MCP subassembly formation. As a reference point, even with wafers builds for 270 μm top dies, the warpage of the wafer is already at marginal levels of acceptability, and will increase as top die thicknesses increase. Thicker dies mean more encapsulation material (e.g. mold) to encapsulate the top dies with a much higher coefficient of thermal expansion than that of a wafer.

Moreover, another disadvantage of the state-of-the-art is that MCP's such as those shown in FIGS. 1A and 1B are made using a temporary bonding and debonding (TBDB) solution as will be explained further below in the context of FIG. 2. Such a solution entails the use of a carrier, typically including glass, to temporarily be bonded to the top dies during part of the process flow before being debonded therefrom. After the temporary bonding of the top dies to the carrier, mold may be provided on the dies, planarized, and the rest of a MCP subassembly may be built thereon. To temporarily attach the top dies to the carrier, an adhesive is used. The top dies on the adhesive tend to shift during the process flow to make a MCP, and as a result create issues with respect to pitch tolerances on the conductive features of other layers of the MCP with which they would need to be electrically coupled.

Referring now more particularly to FIGS. 1A and 1B, the semiconductor package 100 may include a heat spreader 120, a TIM 140A/140B, a plurality of passive heat spreaders 121a and 121b, a plurality of top dies or top dies 110a and 110b (hereinafter top dies 110), a plurality of second dies or side dies 111a and 111b (hereinafter side dies 111), a plurality of substrates 130, and a package substrate 102. The semiconductor package 100 may be a MCP or the like. The MCP 100A/100B as shown includes two MCP subassemblies 149a and 149b (hereinafter MCP subassemblies 149). An individual MCP subassembly includes a first layer 150 and a second layer 152. The first layer 150 includes the top dies 110a or110b, encapsulation material 180, underfill 155, conductive features including conductive pads 118. The second layer 152 includes substrate 130 comprising conductive features therein, such as conductive pads 118 and conductive interconnects 131.

As shown in FIGS. 1A and 1B, the substrates 130 may be disposed over the package substrate 102, where the substrates 130 may be conductively coupled to the package substrate 102 with a plurality of solder balls 123.

The top dies 110 may be disposed over the respective substrates 130, where the top dies 110a are positioned on the top surface of one of the substrates 130, and the top dies 110b are positioned on the top surface of another of the substrates 130. The top dies 110 may have a thin profile (or a low z-height profile), be formed from a material such as silicon (or the like), and have circuitry thereon that is to be coupled to the substrates 130 and/or any other dies, substrates, and so on.

An encapsulation layer 180 may be disposed over the top dies 110 and the substrates 130. The encapsulation layer 180 may further be disposed over an underfill material 155 (or an underfill layer). The underfill material 155 may be disposed over the substrates 130, where the underfill material 155 is disposed between the top surface of the substrates 130 and the bottom surfaces of the top dies 110. The underfill material 155 may be surrounded (or embedded) with portions of the encapsulation layer 180. The underfill material 155 may surround conductive pads and solder balls (or solder bumps) formed between the top dies 110 and the respective substrates 130.

A plurality of side dies 111 may be disposed on the package substrate 102. The side dies 111 may be directly coupled to the top surface of the package substrate 102. The side dies 111 may be positioned adjacent to the outer edges of the respective substrates 130 and TIM 140A/140B. The side dies 111 may have a thickness that is greater than a thickness of the top dies 110. The side die 111a may have a thickness that is substantially equal to a thickness of the side die 111b. Individual ones of the side dies 111 may be a satellite die, a high-bandwidth memory (HBM) die, and/or any other die or electrical device/component with a thickness that may be greater than the thickness of the top dies 110.

A TIM 140A/140B may be disposed over the side dies 111. The TIM 140A/140B may be directly coupled onto the top surfaces of the side dies 111. The TIM layer may have a single monolithic thickness or it may include various TIM sublayers. The solid component coupled to the TIM layer with a backside metallization (BSM) layer.

A heat spreader 120 may be disposed over the TIM 140A/140B. The heat spreader 120 may be manufactured (or shaped) to include a lid and a plurality of legs (or pedestals), where the lid of the heat spreader 120 may be directly disposed on the top surface of the TIM 140A/140B, and the legs of the heat spreader 120 may be directly disposed on the top surface of the package substrate 102. The heat spreader 120 may enclose (or form) a cavity 115 that surrounds the TIM 140A/140B, the passive heat spreader 121a and 121b, the first and side dies 110 and 111, and the substrates 130.

Many of the elements of the semiconductor package 100 of FIGS. 1A and 1B are included in other ones of the accompanying drawings relating to some embodiments. A description of some elements may therefore not be repeated when discussing the drawings to be described below, and any of these elements may take any of the forms disclosed herein.

FIG. 2 is a side cross-sectional view of a temporary subassembly 200 to form a MCP, such as, for example, the MCP 100A/100B of FIG. 1, or the MCP subassemblies 549B/549C of FIG. 5B/5C, as will be explained in further detail below. Thus, although FIG. 2 will be described below in the context of FIGS. 1A and 1B, it is to be understood that its scope is not limited to the state-of-the-art, and it is applicable to some embodiments as will be explained further below.

In FIG. 2, sets of top dies (i.e. dies of a MCP closest to a heat spreader, such as sets of dies 110, are first attached at their backsides (sides to be placed closest to a heat spreader such as heat spreader 120) to a temporary carrier 205, generally a glass carrier, using an organic adhesive 207. The adhesive 207 may be provided by way of lamination, spinning on, etc. onto the temporary carrier 205. The thickness of the adhesive layer 207 may be between 5 to 10 microns, and its thickness may vary appreciably from application to application, as it is not reliably controllable. After placement of dies 110, encapsulation material 180 may be provided to encapsulate the dies 110 therein, and the top surface of the dies 110 and encapsulation material 180 may be planarized to control a thickness of and form the first layer 150. Because of the total thickness variation (TTV) of the adhesive as between different MCP subassemblies 149, top die coplanarity as between MCP subassemblies 149a and 149b may be disadvantageously compromised. The TTV of adhesive layer 207 in the state of art as between different MCP subassemblies may further impact bump reveal for dies 110.

In addition, as noted previously, disadvantageously, die shift is a common issue for a flow such as the state-of-the-art flow to obtain the MCP 100A/100B of FIG. 1. Die shift is impacted by the adhesive and encapsulation process. With a low modulus of elasticity for the adhesive 207, the coupling between top dies 110 and adhesive 207 is not strong. As a result, a shift in a position of the top dies 110 will be driven by a process flow for providing the encapsulation material, the results of which are relatively difficult to control, predict and compensate for.

For a three-dimensional (3D) stacked microelectronic package such as MCP 100A/100B of FIG. 1A/1B, current die thickness is to be less than about 280 μm because of controlled collapse chip connection (C4) tool and temporary carrier limitations, such as limitations of carrier 205 of FIG. 2. Because of the above, as can be seen for package 100A of FIG. 1A, the TIM 140 is provided to have a relatively large thickness as compared with the thickness of the top dies 110, for example a thickness of about 540 μm. In addition, for the same reasons, as can be seen for package 100B of FIG. 1B, not only does the TIM 140 still have a thickness that is much larger than that of the top dies 110, for example about 400 μm, the heat spreader 120 has been modified to include an extension 120′ to compensate for some of the thickness taken away from the TIM 140. Compensation in the above context means adding enough heat conducting height above the MCP subassemblies 149 in order to substantially reach the z height of the side dies 111 for more efficient and controllable attachment of heat dissipation components, such as the TIM and heat spreader.

As is clear from a visual overview of FIGS. 1A and 1B, the state-of-the-art has proposed a heat dissipation solution for MCPs where the TIM is much thicker than the top dies and/or where the heat spreader includes an extension extending therefrom in a direction toward the top surface of the TIM. The solutions proposed in FIGS. 1A and 1B however are complex to implement in ensuring that side dies, such as HPM memory dies, can be easily and reliably integrated next to a MCP subassembly 149, and in ensuring the possibility of using finer pitched conductive features on the second layer 152 to be electrically coupled to the top dies.

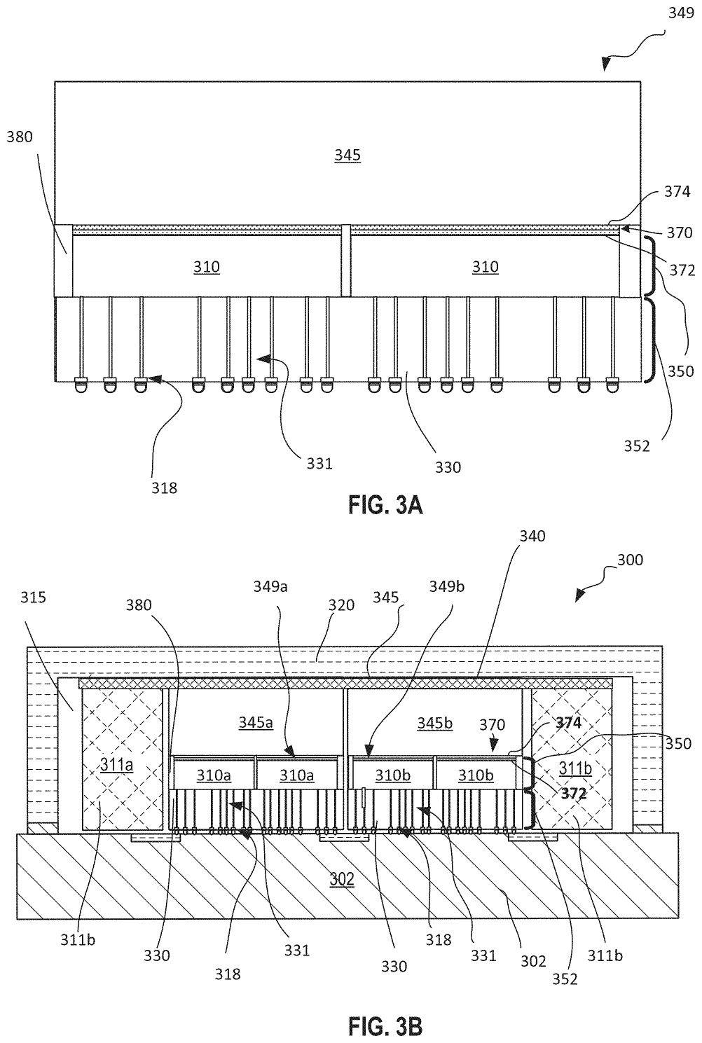

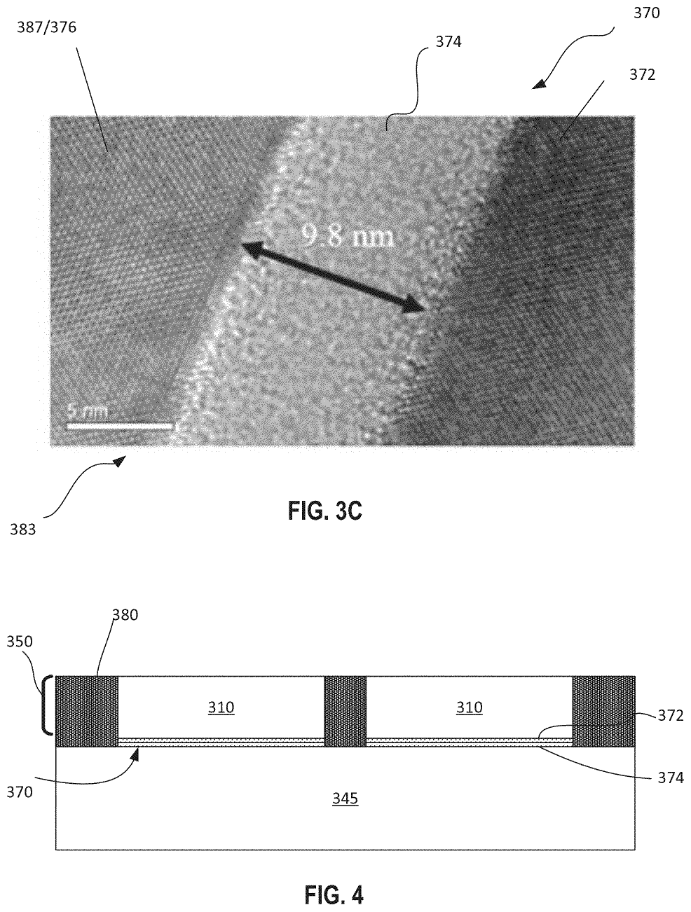

Referring now to FIGS. 3A-3B, cross-sectional views are shown of MCP subassemblies 349a and 349b (hereinafter MCP subassemblies 349) and of a MCP 300 according to some embodiments. FIG. 3C relates to FIGS. 3A and 3B, and is a transmission electron microscopy (TEM) image of a Si'Si direct bonded interface, which may, in one example, correspond to interface 370 of FIGS. 3A and 3B as will be described in further detail below. The MCP subassemblies 349 of FIGS. 3A and 3B are simplified as compared with the corresponding MCP subassemblies 149 of FIG. 1, but may include the same components. In addition, as suggested above, the MCP subassemblies 349 may represent any number of MPC architectures and fabrication approaches, including, for example, a chip first architecture with top die underbumps (as will be explained in more detail in relation to FIG. 5A), a chip first architecture with bumpless top dies (as will be explained in more detail in relation to FIG. 5B), or a chip last architecture (as will be explained in more detail in relation to FIG. 5C).

In FIGS. 3A and 3B, in order to provide heat dissipation from components of the MCP 300s, which includes top dies or top dies 310a and 310b (hereinafter top dies 310) and the much thicker second dies or side dies 311a and 311b (hereinafter side dies 311), propose providing on MCP subassembly 349a/349b (hereinafter MCP subassembly 349), a corresponding passive heat-spreader interposer 345a/345b (hereinafter passive heat-spreader interposer 345), and a dielectric interface layer 370 bonding the MCP subassembly 349 and the passive heat-spreader interposer 345 to one another. In addition, in the embodiment of FIGS. 3A and 3B, because passive heat-spreader interposer 345 compensates for the thickness (or z height) differential as between top dies 310 and side dies 311, it is possible to provide, according to one example, a single TIM layer 340 that extends between a bottom surface of the heat spreader 320 and the top surfaces of the passive heat-spreader interposers 345a and 345b, and the top surfaces of the side dies 311a and 311b. According to an example, top surfaces of the passive heat-spreader interposers 345a and 345b and top surfaces of the side dies 311a and 311b may be substantially coplanar.

The top dies 310 may be thin dies such as a composite die stack, a monolithic silicon die, and/or any other thin die (e.g., a thin embedded multi-die interconnect bridge (EMIB)). The top dies 310a may have a thickness (or z-height) that is substantially equal to a thickness of the top dies 310b. The top dies 310 may include, but are not limited to, a semiconductor die, an electronic device (e.g., a wireless device), an integrated circuit (IC), a central processing unit (CPU), a microprocessor, a platform controller hub (PCH), a memory, and/or a field-programmable gate array (FPGA).

The semiconductor package 300 may include a heat spreader 320, a TIM 340, a plurality of passive heat-spreader interposers, a plurality of top dies 310, a plurality of side dies 311, a plurality of substrates 330, and a package substrate 302. The semiconductor package 300 may be a MCP or the like. The MCP 300 as shown may include two MCP subassemblies 349. An individual MCP subassembly includes a first layer 350 and a second layer 352. The first layer 350 includes corresponding dies 310, encapsulation material 380, underfill (not shown), conductive features including conductive pads 318. The second layer 352 includes substrate 330 including conductive interconnects 331 therein.

Note that, while two substrates 330 are shown in FIGS. 3A and 3B, it is to be appreciated that any number of substrates 330 may be disposed on/over and coupled to the package substrate 302 (e.g., one substrate 330 may be implemented with a larger footprint (or an x-y area) to couple the package substrate 302 to the top dies 310).

The substrates 330 may have a plurality of conductive features including conductive pads 318 and conductive interconnects 331. The conductive pads 318 may be disposed on the bottom surfaces of the substrates 330. The conductive pads 318 may be a plurality of ball-grid array (BGA) pads or the like. The conductive interconnects 331 of the substrates 330 may include conductive vias, traces, lines, pads, or the like. For example, the conductive interconnects 331 may be directly coupled to the conductive pads 318, where the solder balls 323 may conductively couple the first conductive pads 318 of the substrates 330 to the top surface of the package substrate 302. As such, the conductive interconnects 331 of the substrates 330 may communicatively couple the package substrate 302 to a plurality of top dies 310.

The substrates 330 may be a high-density organic substrate such as a high-density package (HDP) substrate or the like. The substrates 330 may include a plurality of redistribution layers (RDLs) comprised of traces with L/S of approximately or less than 2/2 um (i.e., fine/ultrafine traces), lithographically-defined vias, zero-misalignment vias, and/or via pads with fine (or ultrafine) pitches. The substrates 330 may be a silicon substrate having increased (or high) input/output (I/O) density and bandwidth for the communication between the top dies 310 and the package substrate 302. The substrates 330 may have a thickness of approximately 10 μm to 200 μm, or, in an alternative embodiment, a thickness of approximately or less than 10 μm.

The package substrate 302 may include, but is not limited to, a package, a substrate, a printed circuit board (PCB), and/or a motherboard. The package substrate 302 is a PCB. The PCB is made of an FR-4 glass epoxy base with thin copper foil laminated on both sides. For some embodiments, multilayer PCB can be used, with pre-preg and copper foil used to make additional layers. For example, the multilayer PCB may include one or more dielectric layers, where each dielectric layer may be a photosensitive dielectric layer. The PCB 302 may include a plurality of conductive layers, which may further include copper (or metallic) traces, lines, pads, vias, via pads, holes, and/or planes.

The top dies 310 may be disposed over the respective substrates 330, where the top dies 310a are positioned on the top surface of one of the substrates 330, and the top dies 310b are positioned on the top surface of another of the substrates 330. The top dies 310 may have a thin profile (or a low z-height profile), be formed from a material such as silicon (or the like), and have circuitry thereon that is to be coupled to the substrates 330 and/or any other dies, substrates, and so on.

An encapsulation layer 380 may be disposed over the top dies 310 and the substrates 330. The encapsulation layer 380 may include one or more encapsulation materials such as a mold material, an underfill material, a filler material, any similar material(s), and/or any combination thereof. The encapsulation layer 380 may include an epoxy (e.g., a soft epoxy, a stiff epoxy, opaque epoxy, etc.) with one or more filler materials. The encapsulation layer 380 may be compression molded, laminated, or the like. For example, the encapsulation layer 380 may be planarized as the top surface of the encapsulation layer 380 may be substantially coplanar to the top surfaces of the top dies 310, where the encapsulation layer 380 may also be disposed between the outer edges of the top dies 310. Also, the encapsulation layer 380 may be disposed over an underfill material (or an underfill layer—not shown in FIG. 3B). The underfill material may be disposed over the substrates 330, where the underfill material is disposed between the top surface of the substrates 330 and the bottom surfaces of the top dies 310. The underfill material may be surrounded (or embedded) with portions of the encapsulation layer 380. the underfill material may surround conductive pads and solder balls (or solder bumps) formed between the top dies 310 and the respective substrates 330 (e.g., as shown with the underfill material of FIG. 3B).

A plurality of side dies 311 may be disposed on the package substrate 302. The side dies 311 may be directly coupled to the top surface of the package substrate 302. The side dies 311a and 311b may be positioned adjacent to the outer edges of the respective substrates 330 and TIM 340. The side dies 311 may have a thickness that is greater than a thickness of the top dies 310. The side die 311a may have a thickness that is substantially equal to a thickness of the side die 311b. The side dies 311 may be a satellite die, a high-bandwidth memory (HBM) die, and/or any other die or electrical device/component with a thickness that may be greater than the thickness of the top dies 310.

The side dies 311 may include, but are not limited to, a semiconductor die, an electronic device (e.g., a wireless device), an IC, a CPU, a microprocessor, a PCH, a memory (e.g., a HBM die), and/or a FPGA. The side dies 311 may be formed from a material such as silicon (or the like) and have circuitry thereon that is to be coupled onto the package substrate 302.

According to some embodiments, individual ones of passive heat-spreader interposers 345a and 345b (passive heat-spreader interposer 345) may include a dielectric material, such as Si, SiC, or a highly conductive material, including, in come embodiments, a metal. The passive heat-spreader interposer 345 is bonded directly to top dies 310 by way of dielectric interface layer 370 which may include a first dielectric sublayer 372 directly adjacent the first layer 350 (which includes the top dies 310), and a second dielectric sublayer 374 which corresponds to a bonding sublayer formed during a direct dielectric-to-dielectric bonding of the passive heat-spreader interposer 345 with the first layer 350. The existence of an interface layer 370 that includes two sublayers 372 and 374 as shown in FIG. 3A may pertain to an instance where the material of the passive heat-spreader interposer is a dielectric material which is itself directly bonded to the dielectric sublayer 372. In some embodiments, there may be a third dielectric sublayer (see e.g. third dielectric sublayer 376 of FIGS. 3C and 5A-5C) provided on the passive heat-spreader interposer prior to the direct dielectric-to-dielectric bonding with the sublayer 372. In either case, the bonding sublayer 374 may include an inorganic material, such as SiₓN_{y} (e.g. SiN), SiₓO_{y} (e.g. SiO₂), SiₓC_{y}N, (e.g. SiCN), etc. In one example, the bonding sublayer 374 may include an amorphous dielectric material. In one example, the bonding sublayer may include a Si—O—Si or a siloxane bond. In one example, the bonding sublayer may include Si In one example, the interface layer 370 may have a thickness of about 1 to about 2 microns. In one example, the bonding sublayer may have a thickness of about 4 microns to about 12 microns.

A TIM 340 may extend over the MCP subassemblies 349a an 349b, and the side dies 311. The TIM 340 may be directly coupled onto the top surfaces of the side dies 311. The TIM 340 may be a STIM such as an iridium STIM or the like. The TIM 340 may include one or more highly thermal conductivity materials. For example, the TIM 340 may be a metallic TIM, a STIM, a polymer TIM (PTIM), and/or any similar highly thermal conductive material(s). Note that, while one TIM 340 is shown in FIG. 1, it is to be appreciated that any number of TIMs 340 may be disposed on/over and coupled onto the side dies 311 and the passive heat spreaders 321a and 321b. For example, one TIM 340 may be disposed only over the side die 311a and the passive heat spreader 321a, while another, separate TIM 340 may be disposed over the side die 311b and the passive heat spreader 321b, where the two TIMs 340 may have the same thickness or different thicknesses.

A heat spreader 320 may be disposed over the TIM 340. The heat spreader 320 may be manufactured (or shaped) to include a lid and a plurality of legs (or pedestals), where the lid of the heat spreader 320 may be directly disposed on the top surface of the TIM 340, and the legs of the heat spreader 320 may be directly disposed on the top surface of the package substrate 302. The heat spreader 320 may be a heatsink, an IHS, a heat exchanger, a manifold, a cold plate, and/or any similar thermal solution (or device) that may be used to help transfer the heat from the electrical components of the semiconductor package 300 to the ambient environment (or an additional heat spreader).

The heat spreader 320 may enclose (or form) a cavity 315 that surrounds the TIM 340, the passive heat spreader 321a and 321b, the first and side dies 310 and 311, and the substrates 330.

Reference is now made to FIG. 3C, which shows a TEM image of a portion 383 of an example direct bonded Si—Si interface. The Si—Si interface in FIG. 3C may, according to an embodiment, correspond to interface layer 370 of FIGS. 3A-3B. The dielectric layer 387 in FIG. 3C may correspond to a dielectric material of passive heat-spreader interposer 345 of FIGS. 3A and 3B. For the above reason, the parts of interface 385 that may, according to an example, correspond to parts in FIGS. 3A and 3B will be referenced with the same reference numerals as those in FIGS. 3A and 3B. Thus, sublayer 372 in FIG. 3C may be directly adjacent the first layer 350, and sublayer 374 may correspond to a bonding sublayer. Bonding conditions pertaining to the interface include providing oxygen reactive ion etching (RIE) plasma for a time of 60 s at 30 Pa, applying nitrogen radical plasma for a time of 10 s at 30 Pa, and heating the Si—Si at a temperature of 600° C. for 2 h in air. See M. M. R. Howlader, T. Suga, H. Itoh, M. J. Kim, “Sequential Plasma Activated Process for Silicon Direct Bonding,” ECS Transactions, 3 (6) 191-202 (2006). As suggested by the TEM image of FIG. 3C, an interface layer 370 according to some embodiments may include an amorphous bonding sublayer 374 having a thickness in the nanometer range, for example from about 4 nm to about 12 nm. The bonding sublayer 374 represents a bonding of the silicon material of the sublayer 372 closest to the first layer 350, and a dielectric material of layer 387. According to an embodiment, the layer 387 in FIG. 3C may correspond to a third dielectric sublayer of the interface layer 370 that may have been deposited onto the passive heat-spreader interposer surface prior to bonding.

According to some embodiments, the direct dielectric-to-dielectric bonding may be accomplished using any appropriate direct bonding technique, such as hydrophilic, hydrophobic, fusion, and plasma activation bonding. According to an example, direct dielectric-to-dielectric bonding may be performed by joining two flat, mirror-polished and clean dielectric surfaces by any of the noted direct bonding methods above. For example, using a sequential plasma activated bonding (SPAB) process consisting of oxygen reactive ion etching (RIE) and nitrogen microwave radical plasma, silicon direct bonding may be achieved. A silicon oxide bonding sublayer from the SPAB process. The SPAB process can be explained by the reaction between two metastable surfaces, which allows water removal from interface, resulting in covalent Si—O—Si bonding.

Reference is now made to FIGS. 4, and 5A-5C, and to related methods of fabricating the MCP packages as shown in FIGS. 5A-5C. FIGS. 5A-5C represent three embodiments of MPC architectures having corresponding fabrication approaches. FIG. 5A shows a chip first architecture with top die underbumps. FIG. 5B shows a chip first architecture with bumpless top dies. FIG. 5C shows a chip last architecture. Any of the MCPs of FIGS. 5A, 5B or 5C may correspond to the MCP 300 shown and described above in the context of FIGS. 3A-3B. As a result, in FIGS. 5A-5C, like elements as between FIGS. 5A-5C on the one hand, and FIGS. 3A-3B on the other hand, have been designated with like reference numerals, and will not be described again in detail below in the context of FIGS. 5A-5C. Elements in FIGS. 5A-5C that are different from those depicted in FIGS. 3A-3B will be designated with different reference numerals in FIGS. 5A-5C starting with the number “5.”

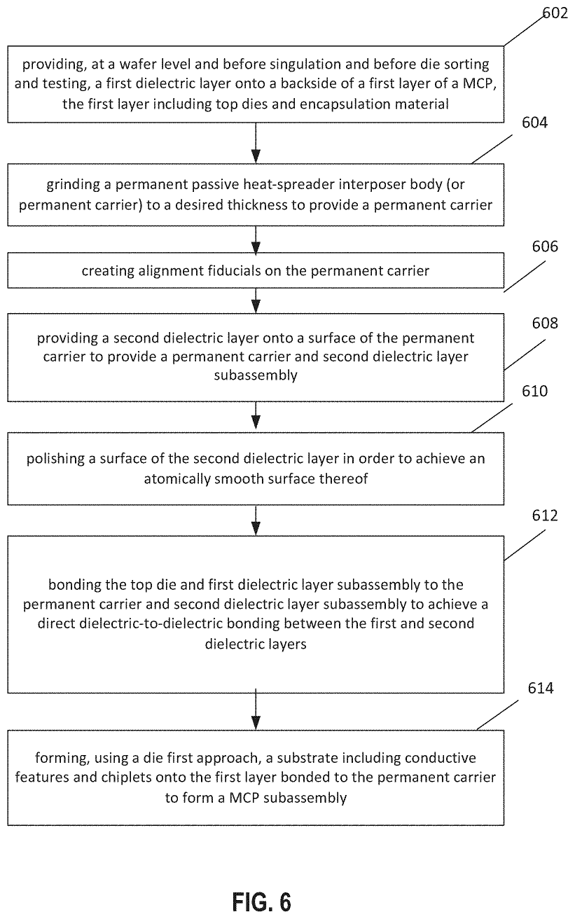

Reference is first made to FIG. 4, which shows a permanent subassembly 400 including first layer 350 therein comprising dies 310 and encapsulation material 380, and an interposer 345 supporting the same as a permanent carrier. In FIG. 4, a dielectric interface layer 570 bonds the interposer 345 with the first layer 350 by way of a direct dielectric-to-dielectric bond, and includes two dielectric sublayers, including first dielectric sublayer 372, and second dielectric sublayer or bonding sublayer 374. A third dielectric sublayer (not shown in FIG. 4, but shown in FIGS. 5A-5C described below) may also be provided and may corresponds to a layer provided onto the passive heat-spreader interposer 345 prior to bonding of the same to the MCP subassemblies according to one embodiment. The permanent subassembly 400 of FIG. 4 may, according to some embodiments, may be used in a process to make a MCP featuring a chip first architecture including dies with underbumps as depicted in FIG. 5A, an example such process explained in detail in FIG. 6.

Referring now to FIGS. 5A-5C, cross-sectional views are shown of MCP subassembly 549A/549B/549C and its corresponding to a MCP 300 as shown in FIGS. 3A-3B according to some embodiments. The MCP subassemblies 549A/549B/549C of FIGS. 5A-5C show further details of and correspond to the MCP subassemblies 349 of FIGS. 3A-3B.

Similar to FIGS. 3A-3B, a number of elements are illustrated in FIGS. 5A-5C, although embodiments are not so limited, and may include fewer elements or more elements than those depicted. In some embodiments, a MCP package including any of the MCP subassemblies or semiconductor subassemblies 549A/549B/549C disclosed herein may serve as a system-in-package (SiP) in which multiple dies 310 and 311 having different functionality. In such embodiments, the semiconductor package 300 may be referred to as a SiP.

FIGS. 5A-5C at the outset show examples of further details of the second layer 352 of FIGS. 3A and 3B. For example, second layer 352 of FIGS. 5A-5C may include, within substrate 330, conductive features such as interconnects 331.

The second layer 352 includes substrate 330 comprising conductive interconnects 331, and in addition, chiplets 590 which may or may not include their own through silicon vias (TSVs). The chiplets 590 may be electrically coupled to each other and to the top dies 310 by way of the interconnects 331.

In addition, the interface layer 570 in FIGS. 5A-5C includes three dielectric sublayers, including first dielectric sublayer 372, second dielectric sublayer or bonding sublayer 374, and a third dielectric sublayer 576 that corresponds to a layer provided onto the passive heat-spreader interposer prior to bonding of the same to the MCP subassemblies 549.

A difference as between MCP subassemblies 549A, 549B and 549C lies in the configuration of the first layer in each of those MCPs, corresponding respectively to first layer 550A, 550B and 550C, everything else in FIGS. 5A-5C being the same as described in the context of FIGS. 3A-3B according to an example. In particular, because MCP subassembly 549A pertains to top dies including underbumps in a chip first architecture, the first layer 550A includes underbumps 518A under the top dies 310 to electrically couple the top dies to substrate 330. Because MCP subassembly 549B pertains to a bumpless die configuration, the first layer 550B does not include underbumps under top dies 310, and presents top dies 310 that are bonded directly to conductive features of the substrate 330. Because MCP subassembly 549C pertains to top dies including underbumps in a chip last architecture, the first layer 550C includes contacts 518C under the top dies 310 to electrically couple the top dies to substrate 330.

In addition to the above, according to some embodiments, fabrication of a MCP subassembly including a passive heat-spreader interposer may include the use of a temporary carrier, such as temporary carrier 205 of FIG. 2 by way of example. Use of a temporary carrier to fabricate a MCP according to some embodiments may for example be applicable to the MCP subassemblies 549B and 549C of FIGS. 5B and 5C, respectively. Use of a temporary carrier in the fabrication of a MCP that includes a passive heat-spreader interposer according to some embodiments may result in a final MCP that features dishing in the encapsulation material, such as dishing as reflected in dishing cavities 585 in the mold material 380 of FIGS. 5B and 5C. The dishing cavities 585 may result, as will be described in further detail below in the context of method for forming MCPs according to some embodiments, from a back grinding of a die subassembly that includes the top dies. The die subassembly will result ultimately in the formation of the first layer 550B/550C that include the dishing cavities. Once a dielectric layer is provided onto the first layer 550B/550C for the purpose of ultimately forming the interface layer 570B/570C, this dielectric layer fills the dishing cavities 585 to form dishing regions 587 in the first layers 550B/550C.

Although a single passive heat-spreader interposer is shown in FIGS. 3A-3B and 5A-5C, embodiments are not so limited, and include within their scope the provision of a plurality of passive interposer heat spreaders over the top surfaces of a same MCP subassembly, or a plurality of passive interposer heat spreaders over the top surfaces of respective MCP subassemblies in a same MCP. For example, one solid component 345 may be disposed over the top dies 310 of one MCP subassembly, while another solid component 345 may be disposed over the top dies 310 of another MCP subassembly. In one embodiment, each of the solid components 345 may have a width that is greater than the combined widths of the respective top dies 310 that it is coupled to. For one embodiment, a solid component 345 may have a width that is substantially equal to a width of the substrate 330 to which it is coupled, or it may have a width that is substantially equal to a combined width of the substrates 330 to which it is coupled, as applicable. In alternate embodiments, the solid component 345 may have a width that is different from a width of the substrates 330 whether individually or combined. It is to be appreciated that any number of solid components 345 may be disposed on/over and coupled onto the top dies 311a-b.

For one embodiment, each of the solid components 345 may be, but is not limited to, a solid component, an interposer, and/or a stiffener. For some embodiments, the solid components 345 may be formed of one or more different substrate/interposer materials, such as silicon (Si), silicon carbide (SiC), or the like, for improved thermal conductivity. For example, the solid components 345 may provide improved warpage control by implementing similar CTE materials for both of the stacked solid component 345 and top dies 310. In one embodiment, the solid component 345 may be bonded (or attached/coupled) to the encapsulation layer 380 and the respective top dies 310 with an interface layer 370/570 through direct dielectric-to-dielectric bonding. For example, the solid components 345 may be directly (or permanently) coupled/attached to the respective top dies 310 at the wafer-level in a chip first approach, or they may be coupled/attached to the top dies 310 at a unit level (after die singulation and KGD reconstitution on a carrier). The interface layer 370/570 may include at least two dielectric sublayers, including a bonding sublayer that is amorphous, such as one containing siloxane bonds.

Note that the MCP of FIGS. 3A-3B or 5A-5C may include fewer or additional packaging components than those depicted in the figures based on the desired packaging design.

According to some embodiments, stacking the solid components 345 and the interface layers 370/570 allows for improved (or enhanced) thermal performance to extract (or dissipate) heat from the respective top dies 310.

FIG. 6 shows a process 600 to make a MCP subassembly or semiconductor subassembly that that is based on a chip first architecture for dies with underbumps, similar to the MCP subassembly 549A of FIG. 5A, according to some embodiments. Although the description of process 600 below is given in some instances in the context of FIG. 5A, it is to be understood that embodiments are not so limited, and may be applicable to any chip first architecture of a MCP.

At operation 602, process 600 includes top die preparation, which includes providing a first dielectric layer (corresponding for example to first dielectric sublayer 372 of FIG. 5A), onto a backside of a first layer of a MCP subassembly that includes top dies and encapsulation material (corresponding for example to first layer 550A of FIG. 5A), such as MCP subassembly 549A of FIG. 5A, at a wafer-level before singulation and before die sorting and testing. Provision of the first dielectric layer onto a backside of a first layer of a MCP subassembly according to operation 602 may result in the formation of a top die and first dielectric layer subassembly. The first dielectric layer provided onto the first layer of a MCP subassembly may include, for example, SiO2, SiCN or SiN. After provision of the first dielectric layer onto the backside of the first layer of a MCP subassembly, the top die and first dielectric layer subassembly may be cleaned prior to bonding to a passive heat-spreader interposer, such as passive heat-spreader interposer 345 of FIG. 5A. In addition, a surface of the first dielectric layer may be polished, for example using CMP, to meet the surface flatness required to achieve direct dielectric-to-dielectric bonding.

At operation 604, the process may optionally include grinding a permanent passive heat-spreader interposer body (or permanent carrier) to a desired thickness to provide a permanent carrier, corresponding for example to interposer 345 of FIG. 5A.

At operation 606, process 600 may optionally include creating alignment fiducials on the permanent carrier, such as by depositing a seed layer, for example a Ti or Cu seed layer, and performing a lithography and etch process on the seed layer to provide the alignment fiducials.

At operation 608, process 600 includes providing a second dielectric layer, corresponding for example to second dielectric sublayer 374 of FIG. 5A, onto a surface of the permanent carrier to provide a permanent carrier and second dielectric layer subassembly. Provision of the second dielectric layer may include either depositing the second dielectric layer, for example using plasma enhanced chemical vapor deposition (PECVD) or chemical vapor deposition (CVD) compatible with a high temperature process, or growing the second dielectric layer onto the surface of the permanent carrier. For example, the second dielectric layer may include a silicon oxide material grown on a silicon wafer by way of thermal processing to oxidize the surface of the wafer.

At operation 610, process 600 includes polishing a surface of the second dielectric layer in order to achieve an atomically smooth surface thereof For example, chemical mechanical polishing (CMP) may be used to polish the surface of the second dielectric layer to a roughness of less than 0.5 nm Ra.

At operation 612, process 600 includes bonding the top die and first dielectric layer subassembly to the permanent carrier and second dielectric layer subassembly to achieve a direct dielectric-to-dielectric bonding between the first and second dielectric layers, in this way creating an interface layer similar to interface layer 570 of FIG. 5A. The bonding may be achieved with the top dies facing up on the permanent carrier. The bonding may include annealing the top die and first dielectric layer subassembly during bonding with the permanent carrier and second dielectric layer subassembly.

At operation 614, process 600 may include forming, using a die first approach, a substrate including conductive features and chiplets onto the first layer bonded to the permanent carrier. The substrate may correspond to substrate 330 of FIG. 5A. Attaching and electrically coupling the substrate may include building the substrate onto the front side of the first layer such that the conductive features of the substrate can be coupled to bumps of the die, such as to bumps 518A of FIGS. 5A. Forming the substate onto the first layer results in the formation of a MCP subassembly such as MCP subassembly 549A of FIG. 5A.

In the die first approach, as is suggested by process 600, a temporary carrier for the first layer, such as carrier 205 of FIG. 2, is obviated through the use of an interposer 545 which doubles as a permanent carrier to carry the first layer including the top dies thereon during formation of the substrate including chiplets thereon. Use of a permanent carrier instead of a temporary carrier advantageously allows more predictable control of a positioning of top dies during MCP fabrication (since the top dies are more securely bonded onto their permanent carrier by virtue of the direct dielectric-to-dielectric bond as compared with an adhesive layer, in this manner allowing tighter conductive feature pitches on the underlying substrate of the MCP subassembly that are to be electrically coupled to the top dies, and thus offering much more flexible scaling solutions as compared with the state-of-the-art.

FIG. 7 shows a process 700 to make a MCP subassembly or semiconductor subassembly that that is based on a chip first architecture for bumpless dies, similar to the MCP subassembly 549B of FIG. 5B, or on a chip last architecture, similar to the MCP subassembly 549C of FIG. 5C. Although the description of process 700 below is given in some instances in the context of FIG. 5C, it is to be understood that embodiments are not so limited, and are applicable to any chip last architecture of a MCP, or any bumpless chip first architecture.

At operation 702, the process 700 includes providing a solid component body, such as one including a dielectric, such as Si or SiC.

At operation 704, the process may optionally include grinding the solid component body to a desired thickness to provide a solid component interposer, corresponding for example to interposer 345 of FIG. 5C.

At operation 706, process 700 includes providing a dielectric layer, corresponding for example to second dielectric sublayer 374 of FIG. 5C, onto a surface of the interposer to provide an interposer and dielectric layer subassembly. Provision of the dielectric layer may include either depositing the dielectric layer, for example using plasma enhanced chemical vapor deposition (PECVD) or chemical vapor deposition (CVD) compatible with a high temperature process, or growing the dielectric layer onto the surface of the interposer. For example, the dielectric layer may include a silicon oxide material grown on a silicon wafer by way of thermal processing to oxidize the surface of the solid component body.

At operation 706, process 700 includes polishing a surface of the dielectric layer in order to achieve an atomically smooth surface thereof. For example, chemical mechanical polishing (CMP) may be used to polish the surface of the dielectric layer to a roughness of less than 0.5 nm Ra.

At operation 708, process 700 may include providing a temporary carrier such as a glass carrier, corresponding for example to temporary carrier 205 of FIG. 2.

At operation 710, process 700 may optionally include creating alignment fiducials on the temporary carrier, such as by depositing a seed layer, for example a Ti or Cu seed layer, and performing a lithography and etch process on the seed layer to provide the alignment fiducials.

At operation 712, process 700 includes providing an adhesive layer, corresponding for example to adhesive layer 207 of FIG. 2, onto a surface of the temporary carrier. Provision of the adhesive layer may include coating or laminating the adhesive layer onto the temporary carrier.

At operation 714, process 700 includes reconstituting top dies, such as known-good-dies (KGDs) onto the adhesive in a face down manner, with the backsides of the top dies exposed. Reconstituting the top dies onto the temporary carrier may result in a temporary carrier and top die subassembly.

At operation 716, process 700 includes providing an encapsulation material, such as mold onto the temporary carrier and top die subassembly to encapsulate the top dies, providing the encapsulation material including for example curing the encapsulation material. Provision of the encapsulation material may result in a temporary carrier and first layer subassembly, where the first layer includes the top dies and the encapsulation material.

At operation 718, process 700 includes grinding a backside of the temporary carrier and first layer subassembly. Because of the different removal rates as between the material of the top dies (e.g. silicon) and that of the encapsulation material, dishing cavities may result in the encapsulation material, such as dishing cavities 585 of FIG. 5C.

At operation 720, process 700 includes providing a first dielectric layer, corresponding for example to first dielectric sublayer 372 of FIG. 5C, onto a surface of the first layer (which includes the top dies and the encapsulation layer) to provide a temporary carrier-first layer-first dielectric layer subassembly. In this context, the “dielectric layer” provided in operation 706 is a “second dielectric layer” and the “interposer and dielectric layer subassembly” is an “interposer and second dielectric layer subassembly.” Provision of the first dielectric layer may include depositing the second dielectric layer, for example using plasma enhanced chemical vapor deposition (PECVD) or chemical vapor deposition (CVD) compatible with a high temperature process.

At operation 722, process 700 includes polishing a surface of the first dielectric layer in order to achieve an atomically smooth surface thereof. For example, chemical mechanical polishing (CMP) may be used to polish the surface of the first dielectric layer to a roughness of less than 0.5 nm Ra.

At operation 724, process 700 includes bonding the temporary carrier-first layer-first dielectric layer subassembly to the interposer and second dielectric layer subassembly to achieve a direct dielectric-to-dielectric bonding between the first and second dielectric layers, in this way creating an interface layer, for example similar to interface layer 570 of FIG. 5C. The bonding may be achieved with the top dies facing up on the temporary carrier. The bonding may include annealing the top die and first dielectric layer subassembly during bonding with the temporary carrier and second dielectric layer subassembly.

At operation 726, process 700 may include providing a substrate including conductive features and chiplets onto the first layer and attaching and electrically coupling the substrate to the top dies. The substrate may correspond to substrate 330 of FIG. 5B or FIG. 5C. Attaching and electrically coupling the substrate may include building the substrate, in a chip first approach as per FIG. 5B, onto the front side of the first layer such that the conductive features of the substrate can be coupled the die. Attaching and electrically coupling the substrate may include providing an already fabricated substrate, in a chip last approach as per FIG. 5C, onto the front side of the first layer such that the conductive features of the substrate can be coupled to contacts of the die.

After the processes 600 and 700 described above, a state of the art flow may be followed in order to form a semiconductor package that includes the MCP subassembly (or semiconductor subassembly). The state of the art flow may include molding, grinding, polishing, redistribution layer processes, providing plates, pillars and pads, attaching chiplets, etc.

Reference is now made to Table 1 below, which is a thermal conductivity table below showing some benefits of proposed embodiments when comparing mold thermal conductivity versus the conductivity of materials to be used for the solid component and the interface layer according to some examples. As far as contact resistance, a low impact is expected from a direct dielectric-to-dielectric interface, such as a SiN bond interface, as no air gap is expected on the bond interface in such a case.

TABLE 1

| | Thermal conductivity |
|---|---|
| Material | (W/mK) |
| Standard Si N | 25-40 |
| Standard SiO2 | 1-5 |
| Mold | 1-4 |
| Indium | 70 |
| Si | 110-148 |
| SiC | 300-500 |
| Epoxy | 0-14 |

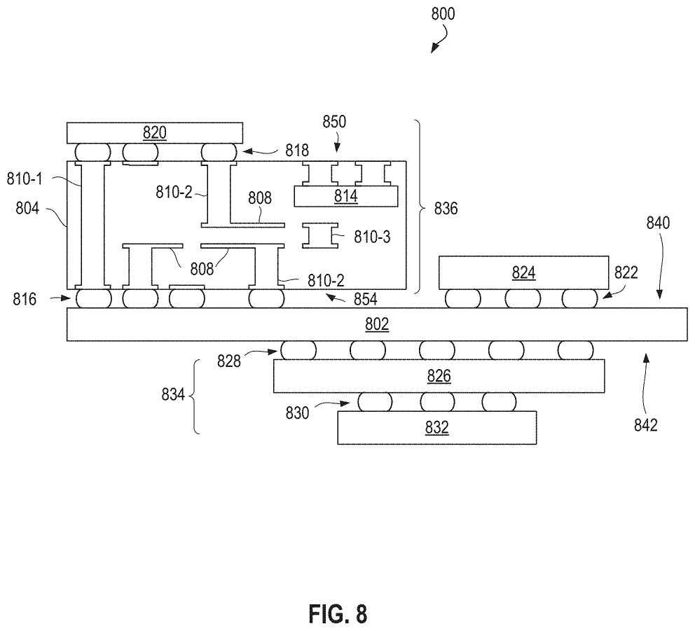

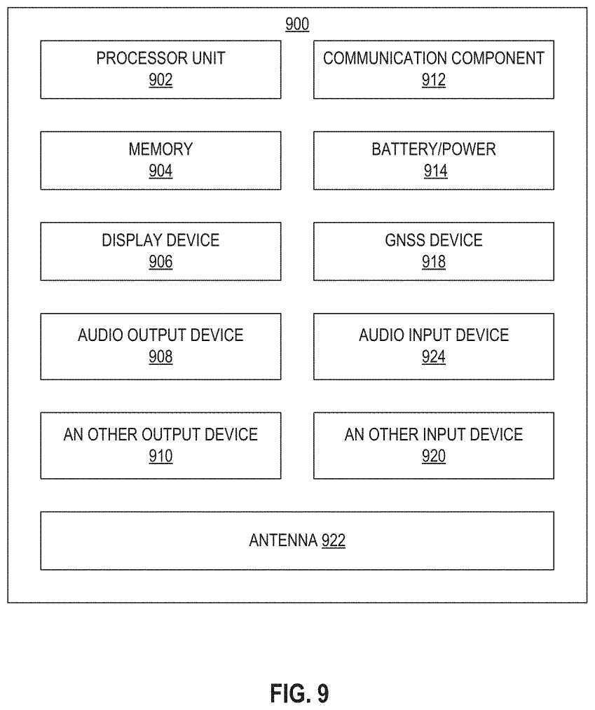

FIGS. 8 and 9 show some examples of an architecture that may include one or more MCP similar to the MCP's described above in the context of embodiments. In the description of FIGS. 8 and 9, mentioned interposers or interposer structures, such as interposer structure 836 or interposer 804, do not necessarily refer to a passive heat-spreader interposer according to embodiments, but may rather refer to any interposer within the knowledge of a person skilled in the art and based on the details provided below.

FIG. 8 is a cross-sectional side view of an integrated circuit device assembly 800 that may include one or more integrated circuit structures each including any of the MCP packages of embodiments described herein. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may include an integrated circuit structure including a cascaded a MCP as disclosed herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more of the embodiment MCPs disclosed herein. For example, any suitable ones of the components of the electrical device 900 may include one or more of the integrated circuit device assemblies 800, integrated circuit components 820, and/or embodiment MCPs disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include one or more antennas, such as antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

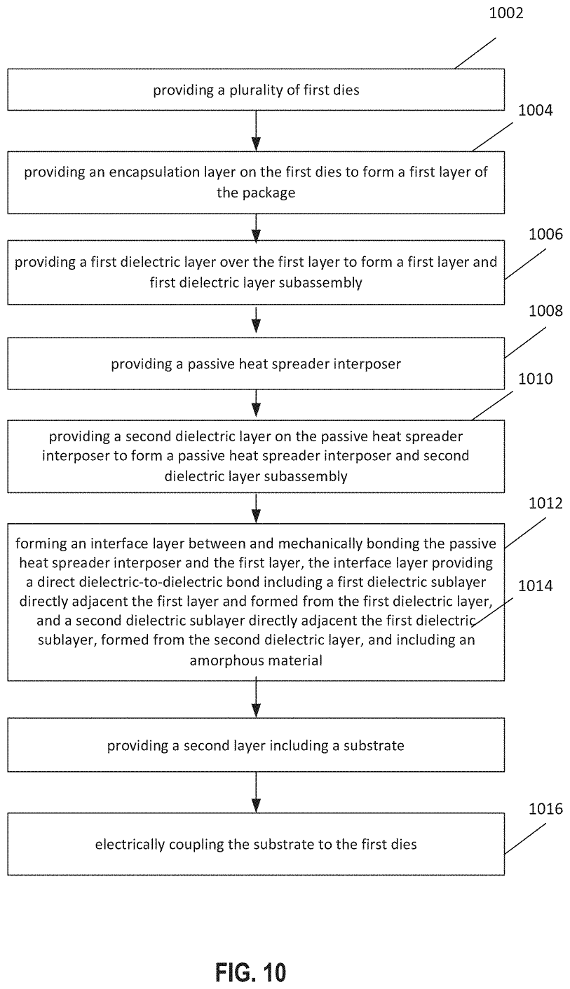

FIG. 10 is a flow chart of a process 1000 according to some embodiments. At operation 1002, the process includes providing a plurality of first dies. At operation 1004, the process includes providing an encapsulation layer on the first dies to form first layer of the semiconductor subassembly. At operation 1006, the process includes providing a first dielectric layer over the first layer to form a first layer and first dielectric layer subassembly. At operation 1008, the process includes providing a solid component. At operation 1010, the process includes providing a second dielectric layer on the solid component to form a solid component and second dielectric layer subassembly. At operation 1012, the process includes forming an interface layer between and mechanically bonding the solid component and the first layer, the interface layer providing a direct dielectric-to-dielectric bond including a first dielectric sublayer directly adjacent the first layer and formed from the first dielectric layer, and a second dielectric sublayer directly adjacent the first dielectric sublayer, formed from the second dielectric layer, and including an amorphous material. At operation 1014, the process includes providing a second layer including a substrate. At operation 1016, the process includes electrically coupling the substrate to the first dies.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

The use of reference numerals separated by a “/”, such as “102/104” for example, is intended to refer to 102 or 104 as appropriate. Otherwise, the forward slash (“/”) as used herein means “and/or.”

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one MCP including an interposer bonded to a MCP subassembly through direct dielectric-to-dielectric bonding as described herein.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e. one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

As used herein, an “integrated circuit structure” may include one or more microelectronic dies.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### EXAMPLES

Some non-limiting example embodiments are set forth below.

Example 1 includes a semiconductor subassembly, comprising: a first layer including one or more dies, and an encapsulation material encapsulating the one or more dies; a second layer adjacent the first layer and electrically coupled thereto, the second layer including a substrate; a solid component disposed on the first layer; and an interface layer disposed between and mechanically bonding the solid component and the first layer, the interface layer providing a direct dielectric-to-dielectric bond including a first dielectric sublayer directly adjacent the first layer, and a second dielectric sublayer directly adjacent the first dielectric sublayer and including an amorphous material.

Example 2 includes the subject matter of Example 1, wherein the solid component includes a silicon (Si) material or a silicon carbide (SiC) material.

Example 3 includes the subject matter of Example 1, wherein the solid component includes a metal material.

Example 4 includes the subject matter of Example 1, wherein the interface layer includes at least one of a Si material or a SiC material.

Example 5 includes the subject matter of Example 1, wherein the second dielectric sublayer includes siloxane bonds.

Example 6 includes the subject matter of Example 1, wherein the first dielectric sublayer includes at least one of a SiN material, a SiO2 material, or a SiCN material.

Example 7 includes the subject matter of Example 1, wherein the interface layer has a thickness between about 1 micron and about 2 microns, and the second dielectric sublayer has a thickness between about 4 nm and about 12 nm.

Example 8 includes the subject matter of Example 1, wherein the interface layer includes a third dielectric sublayer disposed directly adjacent the solid component.

Example 9 includes the subject matter of Example 1, wherein the first layer defines cavities therein at one or more sides of individual ones of the one or more dies, and wherein the first dielectric sublayer includes protruding regions extending into the cavities.

Example 10 includes a semiconductor package including: a package substrate; a semiconductor subassembly disposed on the package substrate and including: a first layer including one or more first dies, and an encapsulation material encapsulating the one or more dies; a second layer adjacent the first layer and electrically coupled thereto, the second layer including a substrate; a solid component disposed on the first layer; and an interface layer disposed between and mechanically bonding the solid component and the first layer, the interface layer providing a direct dielectric-to-dielectric bond including a first dielectric sublayer directly adjacent the first layer, and a second dielectric sublayer directly adjacent the first dielectric sublayer and including an amorphous material; one or more second dies disposed on the package substrate adjacent the semiconductor subassembly; a heat spreader disposed over the semiconductor subassembly and the one or more second dies; and a thermal interface material (TIM) layer coupled to the heat spreader at one side thereof, and to respective ones of the semiconductor subassembly and the one or more dies at another side thereof

Example 11 includes the subject matter of Example 10, wherein the TIM layer extends between a bottom surface of the heat spreader and top surfaces of the solid component and top surfaces of the first dies.

Example 12 includes the subject matter of Example 11, wherein the top surfaces of the solid component and the top surfaces of the first dies are substantially coplanar.

Example 13 includes the subject matter of Example 10, wherein the heat spreader includes a lid and a plurality of legs, wherein the lid of the heat spreader is directly on a top surface of the TIM layer, and wherein the plurality of legs of the heat spreader are directly on a top surface of the package substrate.

Example 14 includes the subject matter of Example 13, wherein the plurality of first dies have a first thickness that is less than a second thickness of the plurality of second dies, wherein the solid component has a thickness that is greater than the first thickness of the plurality of first dies, wherein the second thickness of the plurality of second dies is substantially equal to a combined thickness of the solid component, the plurality of first dies, and the second layer, wherein the TIM layer has a single monolithic thickness, and wherein the lid of the heat spreader has a single monolithic thickness.

Example 15 includes the subject matter of Example 10, wherein the plurality of second dies include high-bandwidth memory (HBM) dies.

Example 16 includes the subject matter of Example 10, wherein the TIM layer includes a solder TIM (STIM), and wherein the solid component coupled to the TIM layer with a backside metallization (BSM) layer.

Example 17 includes the subject matter of Example 10, wherein the semiconductor subassembly includes a plurality of semiconductor subassemblies, and the solid component one of: includes a plurality of solid components individual ones of which are disposed on respective first layers of the plurality of the plurality of semiconductor subassemblies; or a single solid component shared between the plurality semiconductor subassemblies and disposed on first layers of the plurality of semiconductor subassemblies.

Example18 includes the subject matter of Example 10, wherein the solid component includes a silicon (Si) material or a silicon carbide (SiC) material.

Example 19 includes the subject matter of Example 10, wherein the solid component includes a metal material.

Example 20 includes the subject matter of Example 10, wherein the interface layer includes at least one of a SiO2, SiN or SiCN material.

Example 21 includes the subject matter of Example 10, wherein the second dielectric sublayer includes siloxane bonds.

Example 22 includes the subject matter of Example 21, wherein the first dielectric sublayer includes at least one of a SiN material, a SiO2 material, or a SiCN material.

Example 23 includes the subject matter of Example 10, wherein the interface layer has a thickness between about 1 micron and about 2 microns, and the second dielectric sublayer has a thickness between about 4 nm and about 12 nm.

Example 24 includes the subject matter of Example 10, wherein the interface layer includes a third dielectric sublayer disposed directly adjacent the solid component.

Example 25 includes the subject matter of Example 10, wherein the first layer defines cavities therein at one or more sides of individual ones of the one or more dies, and wherein the first dielectric sublayer includes protruding regions extending into the cavities.

Example 26 includes an integrated circuit (IC) device assembly including: a printed circuit board; and a plurality of integrated circuit components coupled to the printed circuit board, individual ones of the integrated circuit components including one or more semiconductor packages, individual ones of the semiconductor packages including: a package substrate; and a semiconductor subassembly disposed on the package substrate and including: a first layer including one or more first dies, and an encapsulation material encapsulating the one or more dies; a second layer adjacent the first layer and electrically coupled thereto, the second layer including a substrate; a solid component disposed on the first layer; and an interface layer disposed between and mechanically bonding the solid component and the first layer, the interface layer providing a direct dielectric-to-dielectric bond including a first dielectric sublayer directly adjacent the first layer, and a second dielectric sublayer directly adjacent the first dielectric sublayer and including an amorphous material; one or more second dies disposed on the package substrate adjacent the semiconductor subassembly; a heat spreader disposed over the semiconductor subassembly and the one or more second dies; a thermal interface material (TIM) layer coupled to the heat spreader at one side thereof, and to respective ones of the semiconductor subassembly and the one or more dies at another side thereof.

Example 27 includes the subject matter of Example 26, wherein the TIM layer extends between a bottom surface of the heat spreader and top surfaces of the solid component and top surfaces of the first dies.

Example 28 includes the subject matter of Example 28, wherein the top surfaces of the solid component and the top surfaces of the first dies are substantially coplanar.

Example 29 includes the subject matter of Example 26, wherein the heat spreader includes a lid and a plurality of legs, wherein the lid of the heat spreader is directly on a top surface of the TIM layer, and wherein the plurality of legs of the heat spreader are directly on a top surface of the package substrate.

Example 30 includes the subject matter of Example 29, wherein the plurality of first dies have a first thickness that is less than a second thickness of the plurality of second dies, wherein the solid component has a thickness that is greater than the first thickness of the plurality of first dies, wherein the second thickness of the plurality of second dies is substantially equal to a combined thickness of the solid component, the plurality of first dies, and the second layer, wherein the TIM layer has a single monolithic thickness, and wherein the lid of the heat spreader has a single monolithic thickness.

Example 31 includes the subject matter of Example 26, wherein the plurality of second dies include high-bandwidth memory (HBM) dies.

Example 32 includes the subject matter of Example 26, wherein the TIM layer includes a solder TIM (STIM), and wherein the solid component coupled to the TIM layer with a backside metallization (BSM) layer.

Example 33 includes the subject matter of Example 26, wherein the semiconductor subassembly includes a plurality of semiconductor subassemblies, and the solid component one of: includes a plurality of solid components individual ones of which are disposed on respective first layers of the plurality of the plurality of semiconductor subassemblies; or a single solid component shared between the plurality semiconductor subassemblies and disposed on first layers of the plurality of semiconductor subassemblies.

Example 34 includes the subject matter of Example 26, wherein the solid component includes a silicon (Si) material or a silicon carbide (SiC) material.

Example 35 includes the subject matter of Example 26, wherein the solid component includes a metal material.

Example 36 includes the subject matter of Example 26, wherein the interface layer includes at least one of a SiO2, SiN or SiCN material.

Example 37 includes the subject matter of Example 26, wherein the second dielectric sublayer includes siloxane bonds.

Example 38 includes the subject matter of Example 37, wherein the first dielectric sublayer includes at least one of a SiN material, a SiO2 material, or a SiCN material.

Example 39 includes the subject matter of Example 26, wherein the interface layer has a thickness between about 1 micron and about 2 microns, and the second dielectric sublayer has a thickness between about 4 nm and about 12 nm.

Example 40 includes the subject matter of Example 26, wherein the interface layer includes a third dielectric sublayer disposed directly adjacent the solid component.

Example 41 includes the subject matter of Example 26, wherein the first layer defines cavities therein at one or more sides of individual ones of the one or more dies, and wherein the first dielectric sublayer includes protruding regions extending into the cavities.

Example 42 includes a method to form a semiconductor subassembly of a semiconductor package, the semiconductor subassembly including: providing a plurality of first dies; providing an encapsulation layer on the first dies to form first layer of the semiconductor subassembly; providing a first dielectric layer over the first layer to form a first layer and first dielectric layer subassembly; providing a solid component; providing a second dielectric layer on the solid component to form a solid component and second dielectric layer subassembly; forming an interface layer between and mechanically bonding the solid component and the first layer, the interface layer providing a direct dielectric-to-dielectric bond including a first dielectric sublayer directly adjacent the first layer and formed from the first dielectric layer, and a second dielectric sublayer directly adjacent the first dielectric sublayer, formed from the second dielectric layer, and including an amorphous material; and providing a second layer including a substrate; and electrically coupling the substrate to the first dies.

Example 43 includes the subject matter of Example 42, wherein at least one of the first dielectric layer or the second dielectric layer includes at least one of a SiO2 material, a SiN material or a SiCN material.

Example 44 includes the subject matter of Example 42, wherein providing the plurality of first dies includes providing a wafer including the first dies, and wherein providing the first dielectric layer over the first layer occurs at wafer-level prior to singulation or sorting of the first dies from the wafer.

Example 45 includes the subject matter of Example 42, wherein providing the second layer and electrically coupling the substrate include building the substrate onto the first layer while the first layer is carried on the solid component.

Example 46 includes the subject matter of Example 42, wherein; providing the plurality of first dies includes: providing an adhesive layer on a temporary carrier; and reconstituting known-good-dies corresponding to the first dies with faces down onto the adhesive layer on the temporary carrier; and providing the encapsulation layer includes providing the encapsulation layer after reconstituting.

Example 47 includes the subject matter of Example 45, wherein providing the encapsulation layer includes depositing the encapsulation layer onto the first dies, and grinding a backside of the encapsulation layer and the first dies to form the first layer.

Example 48 includes the subject matter of Example 46, wherein grinding includes causing cavities to form in the encapsulation layer at one or more sides of the first dies, and wherein the first dielectric sublayer includes protruding regions extending into the cavities.

Example 49 includes the subject matter of Example 42, further including polishing a surface of the first dielectric layer and a surface of the second dielectric layer prior to forming the interface layer.

Example 50 includes the subject matter of Example 42, wherein the solid component includes a silicon (Si) material or a silicon carbide (SiC) material.

Example 51 includes the subject matter of Example 42, wherein the solid component includes a metal material.

Example 52 includes the subject matter of Example 42, wherein the interface layer includes at least one of a Si material or a SiC material.

Example 53 includes the subject matter of Example 42, wherein the second dielectric sublayer includes siloxane bonds.

Example 54 includes the subject matter of Example 42, wherein the first dielectric sublayer includes at least one of a SiN material, a SiO2 material, or a SiCN material.

Example 55 includes the subject matter of Example 42, wherein the interface layer has a thickness between about 1 micron and about 2 microns, and the second dielectric sublayer has a thickness between about 4 nm and about 12 nm.

Example 56 includes the subject matter of Example 42, wherein the interface layer includes a third dielectric sublayer disposed directly adjacent the solid component.

Example 57 includes the subject matter of Example 42, wherein the first layer defines cavities therein at one or more sides of individual ones of the one or more dies, and wherein the first dielectric sublayer includes protruding regions extending into the cavities.

What is claimed is:

1. A semiconductor subassembly, comprising:
a first layer including one or more dies, and an encapsulation material encapsulating the one or more dies;
a second layer adjacent the first layer and electrically coupled thereto, the second layer including a substrate;
a solid component disposed on the first layer; and
an interface layer disposed between and mechanically bonding the solid component and the first layer, the interface layer providing a direct dielectric-to-dielectric bond including a first dielectric sublayer directly adjacent the first layer, and a second dielectric sublayer directly adjacent the first dielectric sublayer and including an amorphous material.

2. The semiconductor subassembly of claim 1, wherein the solid component includes a silicon (Si) material or a silicon carbide (SiC) material.

3. The semiconductor subassembly of claim 1, wherein the solid component includes a metal material.

4. The semiconductor subassembly of claim 1, wherein the interface layer includes at least one of a Si material or a SiC material.

5. The semiconductor subassembly of claim 1, wherein the second dielectric sublayer includes siloxane bonds.

6. The semiconductor subassembly of claim 1, wherein the first dielectric sublayer includes at least one of a SiN material, a SiO₂ material, or a SiCN material.

7. The semiconductor subassembly of claim 1, wherein the interface layer has a thickness between about 1 micron and about 2 microns, and the second dielectric sublayer has a thickness between about 4 nm and about 12 nm.

8. The semiconductor subassembly of claim 1, wherein the interface layer includes a third dielectric sublayer disposed directly adjacent the solid component.

9. The semiconductor subassembly of claim 1, wherein the first layer defines cavities therein at one or more sides of individual ones of the one or more dies, and wherein the first dielectric sublayer includes protruding regions extending into the cavities.

10. A semiconductor package including:
a package substrate;
a semiconductor subassembly disposed on the package substrate and including:
a first layer including one or more first dies, and an encapsulation material encapsulating the one or more dies;
a second layer adjacent the first layer and electrically coupled thereto, the second layer including a substrate;
a solid component disposed on the first layer; and
an interface layer disposed between and mechanically bonding the solid component and the first layer, the interface layer providing a direct dielectric-to-dielectric bond including a first dielectric sublayer directly adjacent the first layer, and a second dielectric sublayer directly adjacent the first dielectric sublayer and including an amorphous material;
one or more second dies disposed on the package substrate adjacent the semiconductor subassembly;
a heat spreader disposed over the semiconductor subassembly and the one or more second dies; and
a thermal interface material (TIM) layer coupled to the heat spreader at one side thereof, and to respective ones of the semiconductor subassembly and the one or more dies at another side thereof.

11. The semiconductor package of claim 10, wherein the TIM layer extends between a bottom surface of the heat spreader and top surfaces of the solid component and top surfaces of the first dies.

12. The semiconductor package of claim 11, wherein the top surfaces of the solid component and the top surfaces of the first dies are substantially coplanar.

13. The semiconductor package of claim 10, wherein the heat spreader includes a lid and a plurality of legs, wherein the lid of the heat spreader is directly on a top surface of the TIM layer, and wherein the plurality of legs of the heat spreader are directly on a top surface of the package substrate.

14. The semiconductor package of claim 13, wherein the plurality of first dies have a first thickness that is less than a second thickness of the plurality of second dies, wherein the solid component has a thickness that is greater than the first thickness of the plurality of first dies, wherein the second thickness of the plurality of second dies is substantially equal to a combined thickness of the solid component, the plurality of first dies, and the second layer, wherein the TIM layer has a single monolithic thickness, and wherein the lid of the heat spreader has a single monolithic thickness.

15. The semiconductor package of claim 10, wherein the plurality of second dies include high-bandwidth memory (HBM) dies.

16. The semiconductor package of claim 10, wherein the TIM layer includes a solder TIM (STIM), and wherein the solid component coupled to the TIM layer with a backside metallization (BSM) layer.

17. The semiconductor package of claim 10, wherein the semiconductor subassembly includes a plurality of semiconductor subassemblies, and the solid component one of:
includes a plurality of solid components individual ones of which are disposed on respective first layers of the plurality of semiconductor subassemblies; or
a single solid component shared between the plurality semiconductor subassemblies and disposed on first layers of the plurality of semiconductor subassemblies.

18. An integrated circuit (IC) device assembly including:
a printed circuit board; and
a plurality of integrated circuit components coupled to the printed circuit board, individual ones of the integrated circuit components including one or more semiconductor packages, individual ones of the semiconductor packages including:
a package substrate; and
a semiconductor subassembly disposed on the package substrate and including:
a first layer including one or more first dies, and an encapsulation material encapsulating the one or more dies;
a second layer adjacent the first layer and electrically coupled thereto, the second layer including a substrate;
a solid component disposed on the first layer; and
an interface layer disposed between and mechanically bonding the solid component and the first layer, the interface layer providing a direct dielectric-to-dielectric bond including a first dielectric sublayer directly adjacent the first layer, and a second dielectric sublayer directly adjacent the first dielectric sublayer and including an amorphous material;
one or more second dies disposed on the package substrate adjacent the semiconductor subassembly;
a heat spreader disposed over the semiconductor subassembly and the one or more second dies;
a thermal interface material (TIM) layer coupled to the heat spreader at one side thereof, and to respective ones of the semiconductor subassembly and the one or more dies at another side thereof.

19. The IC device assembly of claim 18, wherein the TIM layer extends between a bottom surface of the heat spreader and top surfaces of the solid component and top surfaces of the first dies.

20. The IC device assembly of claim 19, wherein the top surfaces of the solid component and the top surfaces of the first dies are substantially coplanar.

21. A method to form a semiconductor subassembly of a semiconductor package, the semiconductor subassembly including:
providing a plurality of first dies;
providing an encapsulation layer on the first dies to form first layer of the semiconductor subassembly;
providing a first dielectric layer over the first layer to form a first layer and first dielectric layer subassembly;
providing a solid component;
providing a second dielectric layer on the solid component to form a solid component and second dielectric layer subassembly;
forming an interface layer between and mechanically bonding the solid component and the first layer, the interface layer providing a direct dielectric-to-dielectric bond including a first dielectric sublayer directly adjacent the first layer and formed from the first dielectric layer, and a second dielectric sublayer directly adjacent the first dielectric sublayer, formed from the second dielectric layer, and including an amorphous material;
providing a second layer including a substrate; and
electrically coupling the substrate to the first dies.

22. The method of claim 21, wherein providing the plurality of first dies includes providing a wafer including the first dies, and wherein providing the first dielectric layer over the first layer occurs at wafer-level prior to singulation or sorting of the first dies from the wafer, and wherein providing the second layer and electrically coupling the substrate include building the substrate onto the first layer while the first layer is carried on the solid component.

23. The method of claim 22, wherein;
providing the plurality of first dies includes:
providing an adhesive layer on a temporary carrier; and
reconstituting known-good-dies corresponding to the first dies with faces down onto the adhesive layer on the temporary carrier; and
providing the encapsulation layer includes providing the encapsulation layer after reconstituting.

24. The method of claim 23, wherein providing the encapsulation layer includes depositing the encapsulation layer onto the first dies, and grinding a backside of the encapsulation layer and the first dies to form the first layer, wherein grinding includes causing cavities to form in the encapsulation layer at one or more sides of the first dies, and wherein the first dielectric sublayer includes protruding regions extending into the cavities.

25. The method of claim 21, wherein the solid component includes a silicon (Si) material or a silicon carbide (SiC) material.
